(19) United States
(12) Patent Application Publication
(10) Pub. No.: US 2017/0242054 A1
(43) Pub. Date: Aug. 24, 2017

(54) APPARATUS FOR TESTING A BATTERY-POWERED DEVICE

(71) Applicant: Zwipe AS, Oslo (NO)

(72) Inventor: Ed Montiel, Colorado Springs, CO (US)

(21) Appl. No.: 15/426,716

(22) Filed: Feb. 7, 2017

Related U.S. Application Data
(60) Provisional application No. 62/298,508, filed on Feb. 23, 2016.

(30) Foreign Application Priority Data
Mar. 10, 2016 (GB) 1604138.6

(51) Int. Cl. G01R 1/04; G06K 7/10; H01M 6/14; G06K 19/07; H01M 2/10; H01M 10/0525

(52) U.S. Cl. CPC G01R 1/0416; H01M 2/1044; H01M 10/0525; H01M 6/14; G06K 19/0723; G06K 7/10366

(57) ABSTRACT

An apparatus for testing a battery-powered device is provided. The apparatus is configured to be inserted into a button cell battery slot of the device to provide temporary power for testing the device. The testing apparatus may include a button cell battery, electrical contacts connected to or provided by the button cell battery and configured to engage electrical contacts within the button cell battery slot of the device, and an extension portion shaped to project from the slot when the testing apparatus is inserted into the button battery slot.

### TECHNICAL FIELD

The present invention relates to a testing apparatus for temporarily supplying power to a battery-powered device.

### BACKGROUND OF THE INVENTION

To determine proper manufacturing of a battery powered device, the quality control process requires a testing agent to temporarily provide power to the device. During this testing phase, a battery is inserted into the device to perform the required checks. In one example, the battery used is a 3V lithium button cell battery.

After testing, the battery must be removed for storage of the device. It is undesirable to leave the battery in the device during storage as this will drain the battery and can cause damage. It has been found, however, that removing the battery is quite cumbersome and time consuming. The present invention seeks to provide a solution to this problem.

### SUMMARY OF THE INVENTION

Viewed from a first aspect, the present invention provides a testing apparatus for temporary insertion into a button cell battery slot, the apparatus comprising a button cell battery, electrical contacts connected to or provided by the button cell battery and configured to engage electrical contacts within the slot, and an extension portion shaped to project from the slot when the apparatus is inserted into the button battery slot.

By the above configuration, the device can be tested using the appropriate button cell battery, whilst facilitating simple removal of the battery from the device for storage. Thus, the testing process is sped up, the risk of damage to the device that might be caused trying to remove the button cell battery is reduced, and the risk of harm to the testing agent by electric shocks from handling the battery directly can be reduced.

In one configuration, the button cell battery provides the contacts, i.e. the contacts of the testing apparatus are the contacts of the button cell battery. Thus, when the testing apparatus is inserted into the button cell battery slot of the device, the button cell battery of the testing apparatus is physically within the slot and the extension portion projects away from the battery.

In an alternative configuration, the button cell battery is connected to the contacts and is preferably located away from the contacts such that button cell battery is not physically within the slot when the testing apparatus is inserted into the button cell battery slot of the device. For example, the button cell battery may be located within the extension portion of the apparatus.

Where the contacts are not provided by the button cell battery itself, it will be appreciated that the contacts may be configured to simulate a button cell battery. For example, being of a suitable size and shape to engage with the contacts within the slot. Thus, a positive one of the contacts may be provided on one surface of the testing apparatus and a negative one of the contact may be provided on an opposite surface of the testing apparatus. As a result, when the testing apparatus is inserted into the slot, the button cell battery of the testing apparatus will power the device via the contacts.

The testing apparatus may be configured such that button cell battery is removable from the testing apparatus. For example, the apparatus may comprise a slot or socket configured to receive the button cell battery, wherein the button cell battery is removably received within the slot or socket. Thus, as the battery charge falls with use, it can be replaces so that the devices are always tested with a fresh battery without needing to replace the entire testing apparatus.

Preferably the portion of the testing device to be inserted into the slot has a width approximately equal to or less than the width of the button cell battery. For example, preferably no greater than 120% of the width of the button cell battery, and more preferably no greater than 110% of the width of the button cell battery. In various embodiments, the width is within ±10% of the width of the button cell battery. This ensures that the testing apparatus can be easily fitted into the button cell battery slot of the device to be tested.

The portion of the testing device to be inserted into the slot, i.e. where the contacts are provided, preferably has a thickness approximately equal to the thickness of the button cell battery. For example, preferably within ±20% of the thickness of the button cell battery, and more preferably within ±10% of the thickness of the button cell battery. This ensures that the testing apparatus can be easily fitted into the button cell battery slot of the device to be tested, and that the contacts properly engage with the corresponding contacts within the slot.

The testing apparatus may comprise a housing configured to enclose the button cell battery and expose the contacts. The testing apparatus may comprise a removable cover configured to shield the contacts when not in use. The cover may comprise a cap that can be removed. Alternatively, the cover may comprise a sheath that can be retracted into the housing, for example as the testing apparatus is pushed into the slot. Thus, the testing apparatus reduces the risk of harm to the testing agent.

Whilst various button cell batteries may be used, the button cell battery is preferably a lithium button battery. Such batteries have a high change density, providing much longer battery life than other types of button cell batteries. These types of batteries might be used in devices such as smart RFID tokens, e.g. having an on-board biometric sensor and a biometric verification module.

Preferably, the extension portion is shaped to provide a grip surface, for example to push or pull the apparatus into our out of the slot.

The testing apparatus may comprise a guide portion configured to guide the testing apparatus into the slot. For example, the guide portion may be rounded, tapered or other suitable shape, e.g. such that if the apparatus self-aligns with the slot as it is pushed in. Such a configuration reduces the risk of damage to the apparatus or the device if they are misaligned when being pushed together. Furthermore, it speeds up the process as less precise alignment is required during insertion of the testing apparatus.

Viewed from a second aspect, the present invention also provides a method of testing a battery-powered device having a slot configured to receive a button battery, the method comprising inserting into the slot a testing apparatus described above so as to power the device, performing one or more tests of the device, and removing the testing apparatus. In this method the testing apparatus may optionally comprise any one or more of all of the optional features discussed above.

The test is preferably a test that can only be performed when the device is powered.

Whilst various devices may be tested in this manner, the device is preferably a device having an on-board biometric sensor and a biometric verification module. When powered, the biometric sensor and/or biometric verification module are preferably powered by the testing apparatus. Thus, the tests may comprise testing correct operation of the biometric sensor and/or the biometric verification module.

The tests may include one or more of verifying operation of one or more battery-powered visual indicators of the device, for example by switching them on an off for inspection by the testing agent or by detecting correct operation electrically.

Where the device includes a wireless communication module, such as an RFID chip, NFC chip, or the like, the tests may include testing correct operation of the wireless communication module.

In one embodiment, the device may automatically perform a self-test when powered on. The self-test may include any or all of the above tests. This improves the speed of the testing as the device will automatically test itself as soon as the testing apparatus is inserted into the slot.

The device may comprise a removable cover that prevents access to the slot. The method may thus comprise removing the cover prior to insertion of the testing apparatus and/or replacing the cover after removing the testing apparatus.

The method may further comprise storing the device after removing the testing apparatus.

The present invention also provides a method of testing a plurality of devices, wherein the same testing apparatus is used to test each of the devices is tested using the method described above. Thus, multiple devices can be quickly and easily tested using a single testing apparatus.

### BRIEF DESCRIPTION OF THE DRAWINGS

Certain preferred embodiments of the present invention will now be described in greater detail, by way of example only and with reference to the accompanying drawings, in which:

FIG. 1 illustrates a schematic layout of the components of a battery-powered device;

FIG. 2 illustrates a housing of the battery-powered device;

FIG. 3 illustrates a side view of a testing apparatus for temporarily powering the battery-powered device;

FIG. 4 illustrates a plan view of the battery-powered device, the testing apparatus and a button cell battery; and

FIG. 5 illustrates the testing apparatus inserted into the battery-powered device.

### DETAILED DESCRIPTION

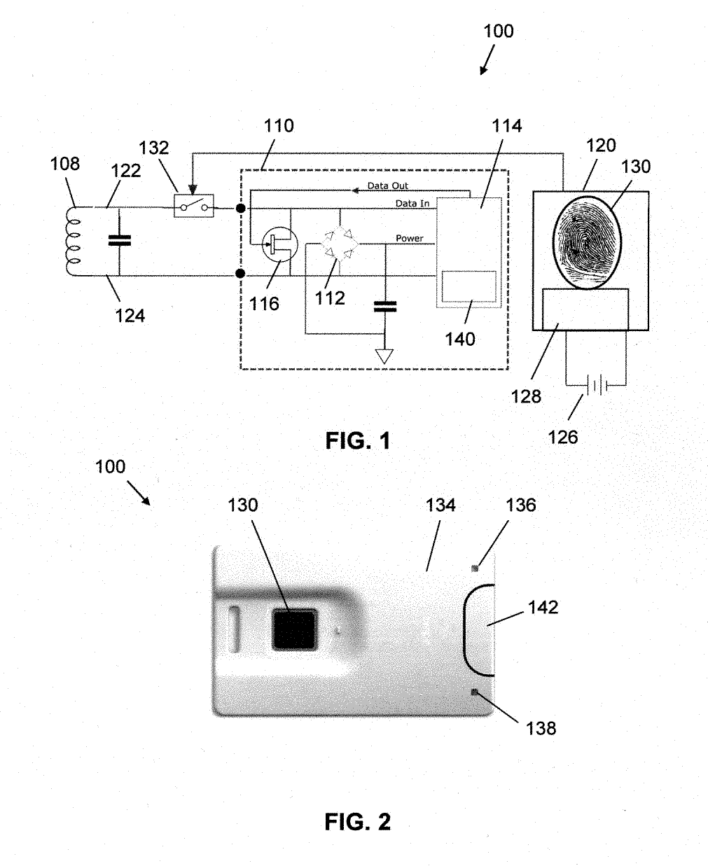

FIG. 1 shows the architecture of a battery-powered, biometric authentication device 100. The biometric authentication device 100 is configured to communicate with a reader (not shown) using an antenna 108. The biometric authentication device 100 comprises a fingerprint authentication engine 120, which includes a processing unit 128 and a fingerprint reader 130. The fingerprint authentication engine 120 is powered by a battery 126. The processing unit 128 comprises a microprocessor that is chosen to be of very low power and very high speed, so as to be able to perform biometric matching in a reasonable time.

The fingerprint authentication engine 120 is arranged to scan a finger or thumb presented to the fingerprint reader 130 and to compare the scanned fingerprint of the finger or thumb to stored reference fingerprint data using the processing unit 128. A determination is then made as to whether the scanned fingerprint matches the reference fingerprint data. Ideally, the time required for capturing a fingerprint image and accurately recognising an enrolled finger is less than one second.

If a match is determined, then an RFID chip 110 is authorised to transmit a signal to the reader. In this embodiment, the RFID chip 110 is activated by closing a switch 132, e.g. between the antenna 108 and the RFID chip 110, to provide power to the RFID chip 110. However, in an alternative embodiment where the RFID chip 110 is powered by the battery 126, the switch 132 may be located between the RFID chip and the battery 126. In yet further alternative embodiments, instead of using a switch 132, the RFID chip 110 may be activated by sending an electronic signal from the fingerprint authentication engine 120 to a controller 114 of the chip 110.

The RFID chip 110 comprises terminals connected to first and second output lines 122, 124 from the antenna 108. When exposed to an excitation field generated by the reader, a voltage is induced across the antenna 108. The voltage received from the antenna 108 is rectified by a bridge rectifier 112 on the chip 110, and the DC output of the rectifier 112 is provided to a controller 114 of the chip 110.

The controller 114 comprises a memory 140 storing data, such as a unique identifier of the card 110. In order to transmit the data to the reader, the data is output from the controller 114 passed to a field effect transistor 116 that is connected across the antenna 108. By switching on and off the transistor 116, a signal can be transmitted by the device 100 and decoded by suitable control circuits in the reader. This type of signalling is known as backscatter modulation and is characterised by the fact that the reader is used to power the return message to itself. However, in other embodiments, the communication from the RFID chip 110 may draw power from the battery 126.

FIG. 2 shows an exemplary housing 134 of the device 100. The circuit shown in FIG. 1 is housed within the housing 134 such that a scanning area of the fingerprint reader 130 is exposed from the housing 134.

The housing 134 may include indicators for communication with the user of the device 100, such as the LEDs 136, 138 shown in FIG. 2. During enrollment, the user may be guided by the indicators 136, 138, which tell the user if the fingerprint has been enrolled correctly. During authorisation, the LEDs may indicate whether or not a match has been determined. The LEDs 136, 138 on the device 100 may communicate with the user by transmitting a sequence of flashes consistent with instructions that the user he has received with the device 100. The LED indicators 136, 138 may be powered by the battery 126.

The housing 134 comprises a slot (not visible) protected by a removable cover 142. The slot is sized to receive a button cell battery 150, and particularly a 3V lithium button cell battery 150. Within the slot are provided electrical contacts that engage the positive and negative terminals of the button cell battery.

To determine proper manufacturing of a biometric authentication device 100, the quality control process requires a testing agent to temporarily provide power to the device 100. During this testing phase, the apparatus 100 is inserted into the slot 142 of the device 100 to power the various electronic components.

Once the device 100 is powered, various tests are performed. Such tests may include one or more of verifying that the indicators 136, 138 function, verifying that the RFID chip 110 functions, verifying that the antenna 108 functions, and verifying that the fingerprint authentication unit 130 functions. In one embodiment, the device 100 is configured to automatically perform a self-test when powered on. The self-test may include any or all of the above tests, and the results of the test may be communicated by the indicators 136, 138. For example, an indicator 136, 138 may illuminate for a short period if all of the tests are successful or flash an error code if one or more of the tests are failed. The error code may indicate which test(s) failed.

After testing, the battery 150 must be removed for storage of the device 100. It is undesirable to leave the battery 150 in the device 100 during storage as this will drain the battery and can cause damage. It has been found, however, that removing the battery 150 is quite cumbersome and time consuming.

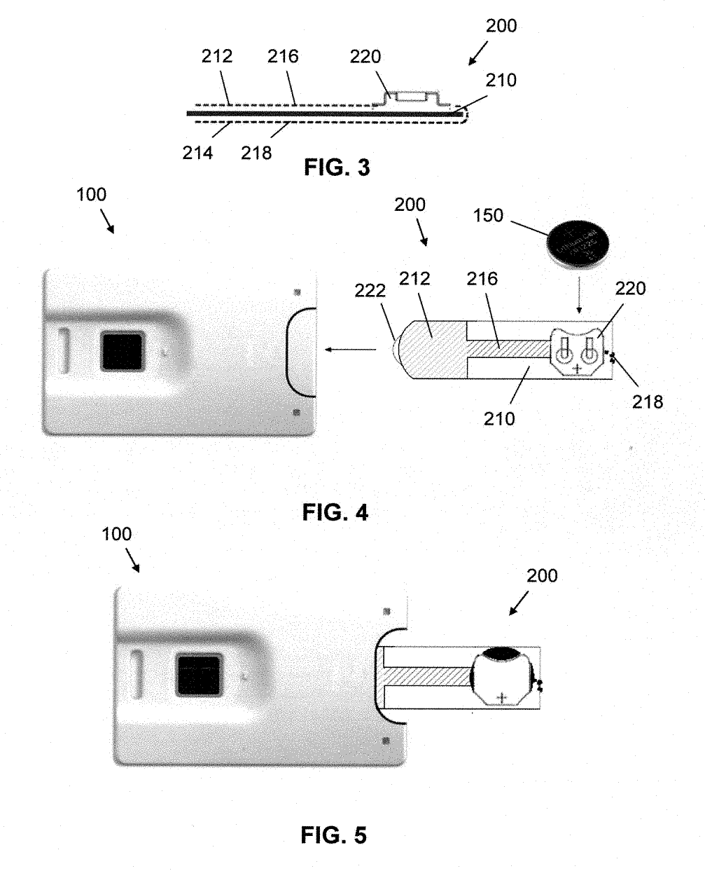

FIGS. 3, 4 and 5 illustrate a testing apparatus 200 for use in place of the battery 150. The testing apparatus 200 comprises an elongate member 210 sized to be inserted into the slot of the device 100. The elongate member 210 is generally planar, and is provided with a first contact 212 on one side of the member 210 and a second contact 214 on the opposite side of the member 210. The contacts 212, 214 are electrically connected by electrical leads 216, 218 to a socket 220 that is sized to receive the battery 150.

The testing apparatus 200 comprises a guide portion 222 at the leading end, i.e. the end to be inserted into the slot. The guide portion extends from the elongate member 220 and serves to centre the apparatus 200 with respect to the slot as it is inserted.

When the battery 150 is inserted into the socket, the contacts are electrically connected to the terminals of the battery 150, such that the device 100 is powered by the battery 150 when the testing apparatus 200 is inserted into the slot of the device 100.

Whilst the testing apparatus 200 is shown in a bare form in the drawings, it is anticipated that in practice it would be provided with a housing so as to prevent damage to the apparatus 200. The housing might, for example, cover the leads 216, 218 and the socket 220 when the device is in use, but leave the contacts 212, 214 exposed. The housing might further be provided with a cap or sleeve to protect the contacts 212, 214 when the apparatus 200 is not in use.

I claim:

1. A testing apparatus for temporary insertion into a button cell battery slot, the apparatus comprising a button cell battery, electrical contacts connected to or provided by the button cell battery and configured to engage electrical contacts within the slot, and an extension portion shaped to project from the slot when the apparatus is inserted into the button battery slot.

2. A testing apparatus according to claim 1, wherein the button cell battery is electrically connected to the contacts and located away from the contacts.

3. A testing apparatus according to claim 1, wherein the contacts are of a size and shape so as to engage with contacts designed to engage terminals of the button cell battery.

4. A testing apparatus according to claim 1, wherein the button cell battery is removable from the testing apparatus.

5. A testing apparatus according to claim 1, wherein a portion of the testing apparatus to be inserted into the slot has a width approximately equal to or less than the width of the button cell battery.

6. A testing apparatus according to claim 1, wherein a portion of the testing apparatus to be inserted into the slot has a thickness approximately equal to the thickness of the button cell battery.

7. A testing apparatus according to claim 1, comprising a housing configured to enclose the button cell battery and expose the contacts.

8. A testing apparatus according to claim 7, comprising a cover configured to shield the contacts when not in use.

9. A testing apparatus according to claim 1, wherein the button cell battery is a lithium button battery.

10. A testing apparatus according to claim 1, wherein the extension portion is shaped to provide a grip surface.

11. A testing apparatus according to claim 1, comprising a guide portion configured to align the testing apparatus with the slot.

12. A method of testing a battery-powered device having a slot configured to receive a button battery, the method comprising:
inserting into the slot a testing apparatus according to any preceding claim so as to power the device;
performing one or more tests of the device; and
removing the testing apparatus.

13. A method according to claim 12, wherein the battery-powered device is a device having an on-board, battery-powered biometric sensor and a biometric verification module, and wherein the at least one test includes testing at least one of the biometric sensor and the biometric verification module.

14. A method according to claim 12, wherein performing one or more tests of the device comprises the device automatically performing a self-test when powered by the testing apparatus.

15. A method according to claim 12, further comprising testing a plurality of battery-powered devices, wherein the same testing apparatus is used to test each of the battery-powered devices.
